(19) United States
(12) Patent Application Publication
(10) Pub. No.: US 2026/0013327 A1
(43) Pub. Date: Jan. 8, 2026

(54) DISPLAY DEVICE AND METHOD FOR FABRICATING THE SAME

(71) Applicant: Samsung Display Co., LTD., Yongin-si (KR)

(72) Inventors: Ki Young YEON, Yongin-si (KR); Jae Bum HAN, Yongin-si (KR); Bo Hwa KIM, Yongin-si (KR)

(73) Assignee: Samsung Display Co., LTD., Yongin-si (KR)

(21) Appl. No.: 19/056,163

(22) Filed: Feb. 18, 2025

(30) Foreign Application Priority Data
Jul. 5, 2024 (KR) 10-2024-0088642

(51) Int. Cl. H10K 59/121; H10D 86/40; H10K 59/12

(52) U.S. Cl. CPC H10K 59/1213; H10D 86/423; H10K 59/1201; H10D 86/431

(57) ABSTRACT

Provided is a display including a substrate including a display area and a non-display area; a first transistor comprising a first semiconductor layer disposed on the display area of the substrate and a first gate electrode disposed on the first semiconductor layer; and a first gate insulator disposed between the first semiconductor layer and the first gate electrode, wherein the first semiconductor layer includes a first layer and a second layer stacked on one another each other in a direction perpendicular to the substrate, and wherein an indium content of the second layer is higher than an indium content of the first layer, and a height of the first layer is lower than a height of the second layer.

### CROSS-REFERENCE TO RELATED APPLICATION(S)

This application claims priority to and benefits of Korean Patent Application No. 10-2024-0088642 under 35 U.S.C. § 119, filed on Jul. 5, 2024, in the Korean Intellectual Property Office, the entire contents of which are incorporated herein by reference.

### BACKGROUND

### 1. Technical Field

The embodiments of the disclosure relate to a display device and a method of fabricating the display device.

### 2. Description of the Related Art

Display devices become more and more important as multimedia technology evolves. Accordingly, a variety of display devices such as liquid-crystal display devices and light-emitting display devices are currently being developed.

### SUMMARY

Aspects of the disclosure provide a display device including oxide semiconductor with high mobility characteristics and a method for fabricating the same.

These and other aspects, embodiments and advantages of the disclosure will become immediately apparent to those of ordinary skill in the art upon review of the Detailed Description and Claims to follow.

The details of one or more embodiments of the subject matter described in this specification are set forth in the accompanying drawings and the description below.

According to an aspect of the disclosure, a display device includes a substrate including a display area and a non-display area; a first transistor including a first semiconductor layer disposed on the display area of the substrate and a first gate electrode disposed on the first semiconductor layer; and a first gate insulator disposed between the first semiconductor layer and the first gate electrode, wherein the first semiconductor layer includes a first layer and a second layer stacked on one another each other in a direction perpendicular to the substrate, and an indium content of the second layer is higher than an indium content of the first layer, and a height of the first layer is lower than a height of the second layer.

In an embodiment, the first layer may include an oxide semiconductor containing indium content of about 30 at % to about 40 at %, and the second layer may include an oxide semiconductor containing indium content of about 65 at % to about 70 at %.

In an embodiment, the first layer may include either indium-gallium-zinc oxide (IGZO) or indium-tin-gallium oxide (ITGO), and the second layer may include indium-tin-gallium-zinc oxide (ITGZO).

In an embodiment, the height of the first layer may range from about 20 angstroms to about 70 angstroms, and the height of the second layer may range from about 100 angstroms to about 200 angstroms.

In an embodiment, the first layer may be in contact with the first gate insulator, and the first gate insulator may include silicon oxide.

In an embodiment, in the first gate insulator, an amount of nitrogen monoxide released may be about 2.5E+18 Molec./cm3 or less, an amount of hydrogen released is about 3E+19 Molec./cm3, and an amount of oxygen released is about 2.76E+19 Molec./cm3 or less under heat treatment conditions carried out at a temperature ranging from about 50° C. to about 550° C.

In an embodiment, the first semiconductor layer may comprise a channel region overlapping the first gate insulator, and a source region and a drain region located on ends of the channel region, the first gate insulator overlaps the channel region, and the first gate insulator may be an insulating pattern that exposes the drain region and the source region.

In an embodiment, the first layer and the second layer may be located to overlap the channel region, the source region and the drain region.

In an embodiment, the first layer and the second layer may overlap the channel region, and the first layer and the second layer may not overlap the source region or the drain region.

In an embodiment, the first semiconductor layer may further include a third layer spaced apart from the first layer in a direction perpendicular to the substrate with the second layer interposed therebetween, the first layer and the third layer may include a same material, a height of the third layer may be lower than a height of the second layer, and the height of the third layer may range from about 20 angstroms to about 70 angstroms.

In an embodiment, the display device may further include a second transistor disposed on the non-display area of the substrate and including a second semiconductor layer and a second gate electrode disposed on the second semiconductor layer; and a second gate insulator disposed between the second semiconductor layer and the second gate electrode.

In an embodiment, the second semiconductor layer may be disposed in a same layer as the first semiconductor layer in the non-display area, and the second semiconductor layer may include a first sub-layer having same material and height as the first layer; and a second sub-layer having same material and height as the second layer, and the second semiconductor layer may be disposed in the non-display area, and may further include a third sub-layer spaced apart from the first sub-layer with the second sub-layer interposed therebetween in a direction perpendicular to the substrate.

According to an aspect of the disclosure, a method for fabricating a display device, the method includes forming a semiconductor layer on a substrate; forming a gate insulator on the semiconductor layer; and forming a gate electrode on the gate insulator, wherein the semiconductor layer includes a first layer, a second layer and a third layer that are stacked on one another in this order, and an indium content of the first layer and an indium content of the third layer are lower than an indium content of the second layer.

In an embodiment, the first layer, the second layer and the third layer may overlap the gate electrode and the gate insulator in a direction perpendicular to the substrate.

In an embodiment, heights of the first layer and the third layer may be lower than a height of the second layer.

According to an aspect of the disclosure, an electronic device may include a display element layer disposed on a substrate, wherein the display element layer includes: a substrate including a display area and a non-display area; a first transistor including a first semiconductor layer disposed on the display area of the substrate and a first gate electrode disposed on the first semiconductor layer; and a first gate insulator disposed between the first semiconductor layer and the first gate electrode, the first semiconductor layer includes a first layer and a second layer stacked on one another each other in a direction perpendicular to the substrate, and an indium content of the second layer is higher than an indium content of the first layer, and a height of the first layer is lower than a height of the second layer.

The electronic device may be at least one of a smart phone, a tablet PC (personal computer), a laptop computer, a television (TV), a desk monitor, wearable electronic devices including smart glasses, a head mounted display, and a smart watch, and vehicle electronic devices including Center Information Display (CID) and a room mirror display arranged on a dashboard, center fascia, and dashboard of an automobile.

According to embodiments of the disclosure, a semiconductor layer overlapping a gate electrode is made up of multiple layers having different indium contents and different heights in a display device, thereby providing an oxide semiconductor having high mobility characteristics.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view showing a display device according to an embodiment of the disclosure.

FIG. 2 is a schematic plan view showing the display panel of FIG. 1.

FIG. 3 is a schematic diagram of an equivalent circuit diagram of a pixel according to an embodiment of the disclosure.

FIG. 4 is a schematic cross-sectional view of the display panel taken along line D-D′ in FIG. 2.

FIG. 5 is an enlarged schematic view of area A in FIG. 4.

FIG. 6 is an enlarged schematic cross-sectional view of the semiconductor layer in FIG. 5.

FIG. 7 is an enlarged schematic cross-sectional view of area A of FIG. 4 according to yet another embodiment.

FIG. 8 is a schematic cross-sectional view showing the display panel across the display area and the non-display area NDA in FIG. 2.

FIG. 9 is an enlarged schematic cross-sectional view of area C of FIG. 8.

FIG. 10 is an enlarged schematic cross-sectional view of area C of FIG. 8 according to yet another embodiment.

FIGS. 11 to 19 are schematic cross-sectional views showing processing steps for fabricating the pixel transistors shown in FIG. 5.

FIG. 20 is a schematic block diagram of an electronic device according to one embodiment of the present disclosure.

FIG. 21 is a schematic diagram of an electronic device according to various embodiments of the present disclosure.

### DETAILED DESCRIPTION OF THE EMBODIMENTS

In the following description, for the purposes of explanation, numerous specific details are set forth in order to provide a thorough understanding of various embodiments or embodiments of the invention. As used herein “embodiments” and “embodiments” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. For example, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Hereinafter, embodiments of the disclosure will be described in detail with reference to the accompanying drawings.

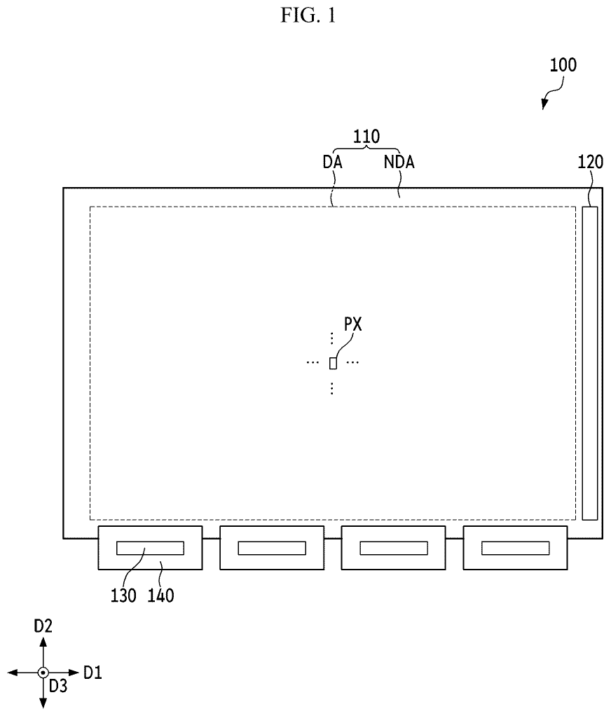

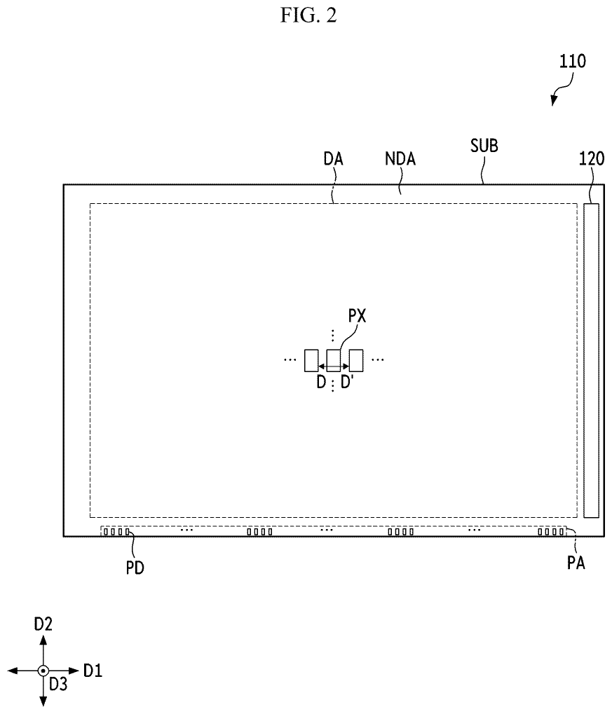

FIG. 1 is a schematic plan view showing a display device according to an embodiment of the disclosure. FIG. 2 is a schematic plan view showing the display panel of FIG. 1.

Referring to FIGS. 1 to 2, a display device 100 is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and an ultra mobile PC (UMPC), as well as the display screen of various products such as a television, a notebook, a monitor, a billboard and the Internet of Things (IoT). Those listed-above are merely as examples, and the display device 100 may be employed in other electronic devices as well.

The display device 100 may be a light-emitting display device such as an organic light-emitting display device including organic light-emitting diodes, a quantum-dot light-emitting display device including quantum-dot light-emitting layer, and an ultra-small light-emitting display device using ultra-small light-emitting diodes such as micro or nano light-emitting diodes (micro LEDs or nano LEDs). However, the disclosure is not limited thereto. For example, the display device 100 may be other types of display devices than light-emitting display devices. In the following description, an organic light-emitting display device is employed as the display device 100.

The display device 100 may include a display panel 110, a first driver 120, and a second driver 130.

In FIGS. 1 and 2, a first direction D1, a second direction D2 and a third direction D3 are defined. The first direction D1 and the second direction D2 may be perpendicular to each other, the first direction D1 and the third direction D3 may be perpendicular to each other, and the second direction D2 and the third direction D3 may be perpendicular to each other. For example, the first direction D1 may be the horizontal direction (e.g., row direction) of the display panel 110, and the second direction D2 may be the vertical direction (e.g., column direction) of the display panel 110. The third direction D3 may be the thickness direction (e.g., height direction) of the display panel 110.

According to the embodiment of the disclosure, the display panel 110 may have a rectangular shape when viewed from a top (e.g., in a plan view). For example, the display panel 110 may include two first sides extended in the first direction D1, and two second sides extended in the second direction D2 intersecting the first direction D1. Although the display panel 110 has the first sides in the horizontal direction larger than the second sides in the vertical length in the example shown in FIGS. 1 and 2, the shape of the display panel 110 is not limited thereto. For example, the display panel 110 may have a shape in which the second sides in the vertical direction are larger than the first sides in the horizontal direction, or may have a shape in which the first sides and the second sides have substantially the same length.

The display panel 110 may include, but is not limited to, angled corners where the first sides and the second sides meet. For example, the display panel 110 may include rounded corners where the first sides and the second sides meet.

The shape of the display panel 110 when viewed from a top (e.g., in a plan view) is not limited to the above-described rectangular shapes but other shapes may be employed. For example, the display panel 110 may have a square shape, a non-square polygonal shape, a circular shape, an oval shape, an irregular shape, or other shapes when viewed from a top (e.g., in a plan view).

The display panel 110 may be substantially flat on the plane defined by the first direction D1 and the second direction D2, and may have a uniform thickness in the third direction D3. According to another embodiment, the display panel 110 may be implemented in a three-dimensional shape having a curved surface, etc.

The display panel 110 may be a rigid display panel that is not substantially deformed, or a flexible display panel that can be deformed, i.e., at least partially folded, bent or rolled. The display panel 110 may be provided to the display device 100 without being bent or with being partially bent.

The display panel 110 may include a substrate SUB and multiple pixels PX disposed on the substrate SUB.

According to the embodiment of the disclosure, the substrate SUB may be a base member for fabricating or providing the display panel 110 and may form a base surface of the display panel 110. The substrate SUB may include a display area DPA, a non-display area NDA and a pad area PD.

The display area DA may have a variety of shapes according to embodiments. For example, the display area DA may have a rectangular shape, a non-rectangular polygonal shape, a circular shape, an elliptical shape, an irregular shape, or other shapes. The display area DA may have, but is not limited to, a shape conforming to the shape of the display panel 110 when viewed from a top (e.g., in a plan view).

The pixels PX may be arranged in the display area DA of the substrate SUB. The pixels PX may be arranged in RGB stripes, RGB delta, PenTile® matrix, or any other geometry.

The non-display area NDA may surround the display area DA. The non-display area NDA may refer to the edge of the substrate SUB. In the non-display areas NDA, multiple circuits for driving the first driver 120 and the display area DA may be disposed.

Multiple pads PD may be disposed in the pad area PA. At least one circuit board 140 may be disposed and/or bonded on multiple pads PD. The pads PD may include signal pads and power pads for transmitting the driving signals and the supply voltages required for driving the pixels PX and/or the first driver 120 to the inside of the display panel 110.

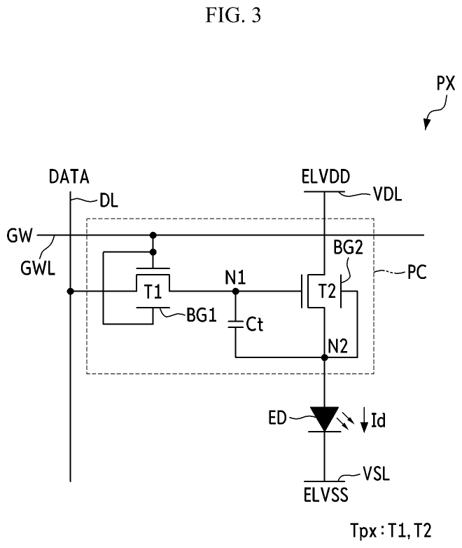

According to the embodiment of the disclosure, the first driver 120 and the second drivers 130 may generate driving signals for controlling the operation timing and brightness of the pixels PX, and may provide the driving signals to the pixels PX. For example, the first driver 120 may be a gate driver including a scan driver, and may be electrically connected to the pixels PX through the respective gate lines. The first driver 120 may provide gate signals (e.g., driving signals that control the operation timing of the pixels PX, such as a gate signal GW of FIG. 3) to the pixels PX. The second drivers 130 may be data drivers including source driver circuits and may be electrically connected to the pixels PX through the respective data lines. The second drivers 130 may supply the respective data signals to the pixels PX.

According to the embodiment of the disclosure, the circuit board 140 may be electrically connected to the display panel 110 through the pads PD. The circuit board 140 may be, but is not limited to, a flexible printed circuit board (FPCB), a printed circuit board (PCB) or a flexible film such as chip on film (COF). The circuit boards 140 may be electrically connected to a timing controller and/or a power supply unit through another circuit board or a connector.

FIG. 3 is a schematic diagram of an equivalent circuit diagram of a pixel PX according to an embodiment of the disclosure. The pixel PX of FIG. 3 is merely an example, and the structure or type of the pixel PX may be altered depending on embodiments.

Referring to FIG. 3 in conjunction with FIGS. 1 and 2, the pixel PX may include a light-emitting element ED and a pixel circuit PC connected to the light-emitting element ED. The light-emitting element ED is a light source of the pixel PX and may be, but is not limited to, an organic light-emitting diode. The pixel circuit PC may provide a driving current Id associated with a data signal DATA to at light-emitting element ED to control the emission of the light-emitting element ED.

The pixel circuit PC may include pixel transistors Tpx and at least one capacitor Ct. For example, the pixel circuit PC may include a first transistor T1, a second transistor T2 and a capacitor Ct. The structure of the pixel circuit PC or the type and number of circuit elements forming the same may vary depending on embodiments. For example, the pixel circuit PC may further include at least one other pixel transistor and/or at least one other capacitor. According to the embodiment of FIG. 3, all of the pixel transistors Tpx are n-type transistors. It should be noted that the type of the pixel transistors Tpx are not limited to this. For example, at least one pixel transistor Tpx may be implemented as a p-type transistor.

The pixel circuit PC may supply the driving current Id to the light-emitting element ED in response to the driving signals supplied from the first driver 120 and the second driver 130. For example, the pixel circuit PC may provide the driving current Id to the light-emitting clement ED in response to at least one gate signal GW (e.g., a scan signal for selecting pixels PX for each horizontal line) supplied from the first driver 120 through at least one gate line GWL (e.g., a scan line connected to pixels PX for each horizontal line), and a data signal DATA supplied from the second driver 130 through a data line DL.

The first transistor T1 may be a switching transistor that is turned on or off depending on the gate-source voltage. The second transistor T2 may be a driving transistor of the pixel PX in which the magnitude of the drain-source current (e.g., driving current Id) is determined depending on the gate-source voltage. Depending on the type (e.g., p-type or n-type transistor) and/or operating conditions of each of the first and second transistors T1 and T2, the first electrode of each of the first and second transistors T1 and T2 may be a drain electrode (or drain region) or a source electrode (or source region) while the second electrode thereof may be an electrode different from the first electrode. For example, if the first electrode of the first transistor T1 is the drain electrode, the second electrode of the first transistor T1 may be the source electrode.

The pixel PX may be electrically connected to the gate line GWL (e.g., a scan line) that transmits a gate signal GW (e.g., a scan signal), and the data line DL that transmits a data signal DATA. The pixel PX may be electrically connected to a first pixel voltage line VDL transmitting a first pixel voltage ELVDD (also referred to as “first pixel supply voltage”), and a second pixel voltage line VSL transmitting a second pixel voltage ELVSS (also referred to as “second pixel supply voltage”).

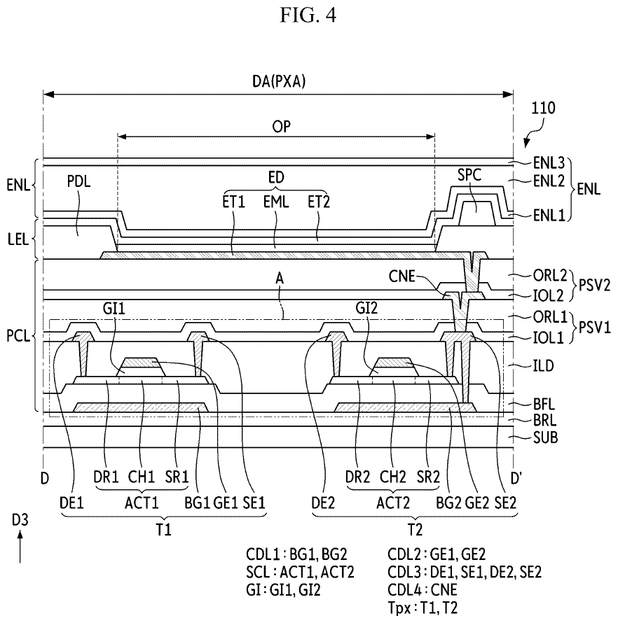

The first transistor T1 and the second transistor T2 may be located in the respective pixel areas (e.g., the pixel area PXA (see FIG. 4) of a pixel PX provided in the display area DA) and may be oxide transistors (also referred to as oxide semiconductor transistors) including an oxide semiconductor (e.g., an oxide semiconductor material). For example, the semiconductor layer (also referred to as an active pattern or a semiconductor pattern) of each of the first transistor T1 and the second transistor T2 may be formed of an oxide semiconductor. However, the embodiments of the disclosure are not limited thereto. For example, at least one pixel transistor Tpx may be formed of a semiconductor material other than an oxide semiconductor (e.g., amorphous silicon or polysilicon).

Oxide semiconductors have high carrier mobility (e.g., high electron mobility in the case of an n-type transistors) and low leakage current, and accordingly, a large voltage drop may not occur even if an oxide transistor is driven for a long period of time. For example, the pixel PX including an oxide transistor can be driven at a low frequency because changes in brightness and/or color of images due to a voltage drop are ignorable even in case that driven at a low frequency. For the display device 100 in which the pixel transistors Tpx include oxide semiconductor, it is possible to reduce or prevent leakage current of the pixels PX and save power consumption.

A bottom electrode (also referred to as a back gate electrode, a counter gate electrode or a bottom electrode) may be disposed under a semiconductor layer forming at least one pixel transistor Tpx. For example, by disposing the bottom electrode under the semiconductor layer of the pixel transistor Tpx including oxide semiconductor, it is possible to block external light. The bottom electrode may face the gate electrode with the semiconductor layer of the pixel transistor Tpx interposed therebetween.

The pixel transistors Tpx may include the bottom electrodes, respectively. For example, the first transistor T1 may include a first bottom electrode BG1, and the second transistor T2 may include a second bottom electrode BG2. By providing the bottom electrodes to the pixel transistors Tpx, it is possible to prevent or reduce current fluctuations of the pixel transistors Tpx due to light, and to stabilize the operating characteristics of the pixel transistors Tpx.

The first transistor T1 may include a gate electrode electrically connected to the gate line GWL, a first electrode electrically connected to the data line DL, and a second electrode electrically connected to a first node N1. The first transistor T1 may be turned on by the gate signal GW (e.g., a scan signal of a gate-on voltage) transmitted to the gate line GWL to electrically connect the data line DL to the first node N1. Accordingly, the data signal DATA transmitted on the data line DL may be transmitted to the first node N1.

The first transistor T1 may further include a first bottom electrode BG1 (or a first back-gate electrode). The first bottom electrode BG1 may be electrically connected to one electrode of the first transistor T1, e.g., the gate electrode. In case that the first bottom electrode BG1 is electrically connected to the gate electrode of the first transistor T1, the operating characteristics of the first transistor T1 can be improved and/or stabilized. For example, as the first transistor T1 may have a double-gate structure, the off characteristics and switching speed of the first transistor T1 can be improved, an additional voltage tolerance can be obtained, leakage current can be reduced, and voltage stability can be improved.

The second transistor T2 may include a gate electrode electrically connected to the first node N1 (or a gate node), a first electrode (e.g., a drain electrode or a drain region) electrically connected to the first pixel voltage line VDL, and a second electrode (e.g., a source electrode or a source region) electrically connected to a second node N2. The second node N2 may be electrically connected to the light-emitting element ED. The second transistor T2 may control the magnitude (e.g., amount of current) of the driving current Id flowing to the light-emitting element ED in response to the data signal DATA transmitted according to the switching operation of the first transistor T1.

The second transistor T2 may further include a second bottom electrode BG2. For example, the second transistor T2 may further include the second bottom electrode BG2 (or a second back-gate electrode) electrically connected to the second node N2. In case that the second bottom electrode BG2 is electrically connected to the second node N2 along with the second electrode of the second transistor T2, the operating characteristics of the second transistor T2 can be improved.

The capacitor Ct may be electrically connected between the first node N1 and the second node N2. For example, the capacitor Ct may be electrically connected between the gate electrode and the second electrode of the second transistor T). The capacitor Ct may be a storage capacitor of the pixel PX and may store a voltage corresponding to a data signal DATA (e.g., data voltage).

The light-emitting element ED may be electrically connected between the pixel circuit PC and the second pixel voltage line VSL. The light-emitting element ED may include a first electrode (e.g., an anode electrode or a pixel electrode), a second electrode facing the first electrode (e.g., a cathode electrode or a counter electrode), and an emissive layer interposed between the first electrode and the second electrode. The first electrode of the light-emitting element ED may be electrically connected to the second node N2. The second electrode of the light-emitting element ED may be electrically connected to the second pixel voltage line VSL. The second electrode of the light-emitting element ED may be a common electrode shared by multiple pixels PX. The light-emitting element ED may emit light with a brightness in proportional to the driving current Id while the driving current Id is supplied from the pixel circuit PC.

FIG. 4 is a schematic cross-sectional view of the display panel taken along line D-D′ in FIG. 2.

Referring to FIG. 4 in conjunction with FIGS. 1 to 3, the display panel 110 according to the embodiment of the disclosure may include a substrate SUB (also referred to as a “base member” or a “base layer”), a panel circuit layer PCL, a light-emitting element layer LEL, and an encapsulation layer ENL. The panel circuit layer PCL, the light-emitting element layer LEL and the encapsulation layer ENL may be disposed or provided on the substrate SUB such that they overlap one another. For example, in the display area DA, the panel circuit layer PCL, the light-emitting element layer LEL and the encapsulation layer ENL may be sequentially disposed or formed on the substrate SUB in the third direction D3. However, the embodiments are not limited thereto. The relative positions of the panel circuit layer PCL, the light-emitting clement layer LEL and/or the encapsulation layer ENL may be changed. For example, the panel circuit layer PCL and the light-emitting element layer LEL may be integrated with each other, or the light-emitting clement layer LEL may be disposed on the panel circuit layer PCL.

According to the embodiment of the disclosure, the substrate SUB may be a base member for forming the display panel 110 and may be a rigid or flexible substrate (or film). The substrate SUB may be a substrate that includes an insulating material such as glass and is rigid, which may not be bendable. According to another embodiment, the substrate SUB may be a flexible substrate that includes polyimide or other insulating material and allows deformation such as bending, folding or rolling, and may be bent or not bent. The type and/or material of the substrate SUB may be altered depending on the embodiments.

The substrate SUB may include the display area DA. In the display area DA, pixel areas PXA may be defined in which the pixels PX are disposed, respectively.

According to the embodiment of the disclosure, a barrier layer BRL may be disposed on the substrate SUB. The barrier layer BRL can protect the pixels PX from moisture permeating through the substrate SUB, which is vulnerable to moisture permeation. The material of the barrier layer BRL may vary depending on embodiments.

The barrier layer BRL may include at least one inorganic layer including an inorganic insulating material (e.g., silicon nitride, silicon oxide, silicon oxynitride, titanium oxide, aluminum oxide, or other inorganic insulating materials).

In some embodiments, the barrier layer BRL may be eliminated. If the barrier layer BRL is eliminated, the substrate SUB and the panel circuit layer PCL may be in contact with each other.

According to the embodiment of the disclosure, the panel circuit layer PCL may be located on the barrier layer BRL. The panel circuit layer PCL may include pixel transistors Tpx, a buffer layer BFL, an interlayer dielectric layer ILD, a first passivation layer PSV1, and a second passivation layer PSV2.

According to the embodiment of the disclosure, the pixel transistors Tpx may be included in the pixel circuit PC of each pixel PX described above with reference to FIG. 3. The pixel transistors Tpx may include a first transistor T1 and a second transistor T2 in the display area DA.

According to the embodiment of the disclosure, the first transistor T1 may include a first conductive layer CDL1, a semiconductor layer SCL, a second conductive layer CDL2, a third conductive layer CDL3, and a fourth conductive layer CDL4. The first transistor T1 may include a first bottom electrode BG1 of the first conductive layer CDL1, a first semiconductor layer ACT1 of the semiconductor layer SCL, a first gate electrode GE1 of the second conductive layer CDL2, and a first drain electrode DE1, and a first source electrode SE1 of the third conductive layer CDL3.

According to the embodiment of the disclosure, the first bottom electrode BG1 included in the first conductive layer CDL1 may be disposed between the substrate SUB and the buffer layer BFL. For example, the first conductive layer CDL1 may be disposed on the barrier layer BRL and covered by the buffer layer BFL.

The first bottom electrode BG1 may overlap the first active layer ACT1 in the third direction D3. For example, the first bottom electrode BG1 may be disposed under the first semiconductor layer ACT1 such that it overlaps at least the first channel region CH1. The first bottom electrode BG1 and the first semiconductor layer ACT1 may be spaced apart from each other by a distance equal to the thickness of the buffer layer BFL. For example, the first bottom electrode BG1 may face the first gate electrode GE1 with the first semiconductor layer ACT1 interposed therebetween.

According to the embodiment of the disclosure, the first semiconductor layer ACT1 included in the semiconductor layer SCL may be disposed between the buffer layer BFL and the interlayer dielectric layer ILD. For example, the first semiconductor layer ACT1 may be disposed on the buffer layer BFL and may be covered by the gate insulator GI and the interlayer dielectric layer ILD.

The first semiconductor layer ACT1 may include a first channel region CH1 overlapping the first gate electrode GE1, and a first source region SR1 and a first drain region DR1 spaced apart from each other in a direction parallel to the substrate SUB with the first channel region CH1 therebetween. The first source region SR1 and the first drain region DR1 may be located on the both ends of the first channel region CH1, respectively.

The first channel region CH1 may not be conductive and can maintain semiconductor properties, and the first source region SR1 and the first drain region DR1 may be conductive regions.

The first semiconductor layer ACT1 may overlap the first bottom electrode BG1 and the first gate electrode GE1 in the third direction D3. The first channel region CH1 of the first semiconductor layer ACT1 may be disposed between the first bottom electrode BG1 and the first gate electrode GE1 in the third direction D3, and may overlap the first bottom electrode BG1 and the first gate electrode GE1.

According to the embodiment, the first gate electrode GE1 included in the second conductive layer CDL2 may be disposed between the gate insulator GI and the interlayer dielectric layer ILD. The first gate electrode GE1 may be located on the first gate insulator GI1 and may be covered by the interlayer dielectric layer ILD.

The first gate electrode GE1 may overlap the first channel region CH1 of the first semiconductor layer ACT1 in the third direction D3. The first gate electrode GE1 and the first semiconductor layer ACT1 may be spaced apart from each other with the first gate insulator GI1 interposed therebetween.

According to the embodiment of the disclosure, the first drain electrode DE1 and the first source electrode SE1 included in the third conductive layer CDL3 may be located between the interlayer dielectric layer ILD and the first passivation layer PSV1. For example, the first drain electrode DE1 and the first source electrode SE1 may be located on the interlayer dielectric layer ILD and covered by the first passivation layer PSV1.

The first drain electrode DE1 may be electrically connected to the first drain region DR1 by at least one contact hole penetrating the interlayer dielectric layer ILD, and the first source electrode SE1 may be electrically connected to the first source region SR1 by at least one contact hole penetrating the interlayer dielectric layer ILD.

According to the embodiment of the disclosure, the second transistor T2 may include a second bottom electrode BG2 of the first conductive layer CDL1, a second semiconductor layer ACT2 of the semiconductor layer SCL, a second gate electrode GE2 of the second conductive layer CDL2, and a second drain electrode DE2 and a second source electrode SE2 of the third conductive layer CDL3.

According to the embodiment of the disclosure, the second bottom electrode BG2 included in the first conductive layer CDL1 may be disposed between the substrate SUB and the buffer layer BFL. For example, the first conductive layer CDL1 may be disposed on the barrier layer BRL and covered by the buffer layer BFL. The first bottom electrode BG1 and the second bottom electrode BG2 may be provided and/or disposed in the same layer on the substrate SUB such that they are spaced apart from each other and may include the same material.

The second bottom electrode BG2 may overlap the second active layer ACT2 in the third direction D3. For example, the second bottom electrode BG2 may be disposed under the second semiconductor layer ACT2 such that the second bottom electrode BG2 overlaps at least the second channel region CH2. The buffer layer BFL may be disposed between the second bottom electrode BG2 and the second semiconductor layer ACT2. The second bottom electrode BG2 and the second semiconductor layer ACT2 may be spaced apart from each other by a distance equal to the thickness of the buffer layer BFL. The second bottom electrode BG2 may face the second gate electrode GE2 with the second semiconductor layer ACT2 interposed therebetween.

According to the embodiment of the disclosure, the second semiconductor layer ACT2 included in the semiconductor layer SCL may be disposed between the buffer layer BFL and the interlayer dielectric layer ILD. For example, the second semiconductor layer ACT2 may be disposed on the buffer layer BFL and may be covered by the second gate insulator GI2 and the interlayer dielectric layer ILD. The first semiconductor layer ACT1 and the second semiconductor layer ACT2 may be provided and/or disposed in the same layer on the substrate SUB such that the first semiconductor layer ACT1 and the second semiconductor layer ACT2 are spaced apart from each other and may include the same oxide semiconductor.

The second semiconductor layer ACT2 may include a second channel region CH2 overlapping the second gate electrode GE2 in the third direction D3, and a second source region SR2 and a second drain region DR2 spaced apart from each other in a direction parallel to the substrate SUB with the second channel region CH2 therebetween. The second source region SR2 and the second drain region DR2 may be located on the both ends of the second channel region CH2, respectively.

The second channel region CH2 may not be conductive and can maintain semiconductor properties, and the second source region SR2 and the second drain region DR2 may be conductive regions.

The second semiconductor layer ACT2 may overlap the second bottom electrode BG2 and the second gate electrode GE2 in the third direction D3. For example, the second channel region CH2 of the second semiconductor layer ACT2 may overlap the second bottom electrode BG2 and the second gate electrode GE2 in the third direction D3.

According to the embodiment of the disclosure, the semiconductor layer SCL may be an oxide semiconductor including indium (In). For example, each of the first semiconductor layer ACT1 and the second semiconductor layer ACT2 may be an oxide semiconductor including indium (In) in a content of about 30 at % (atomic percent) to about 75 at %.

In the display panel 110 according to the embodiment, the atomic ratio of indium (In) contained in the semiconductor layer is controlled within the above range, so that the carrier concentration and/or conductivity of the semiconductor layer can be controlled, and the device characteristics of the transistors (e.g., mobility and threshold voltage) can be controlled and/or ensured. For example, the first semiconductor layer ACT1 and the second semiconductor layer ACT2 can control the characteristics of the first transistor T1 and the second transistor T2 so that each of the first transistor T1 and the second transistor T2 has an appropriate mobility (e.g., an electron mobility in the range of about 60 cm²/Vs or higher) and a threshold voltage (e.g., a threshold voltage of about −2.0 V or higher) for driving the pixels PX. The mobility and the threshold voltage of the first transistor T1 and the second transistor T2 are not limited to the above-mentioned ranges but may vary depending on design conditions or driving conditions of the display panel 110.

According to the embodiment of the disclosure, the second gate electrode GE2 included in the second conductive layer CDL2 may be disposed between the gate insulator GI and the interlayer dielectric layer ILD. For example, the second gate electrode GE2 may be located on the second gate insulator GI2 and may be covered by the interlayer dielectric layer ILD. The first gate electrode GE1 and the second gate electrode GE2 may be provided and/or disposed in the same layer such that they are spaced apart from each other.

The second gate electrode GE2 may overlap the second channel region CH2 of the second semiconductor layer ACT2 in the third direction D3. The second gate electrode GE2 and the second semiconductor layer ACT2 may be spaced apart from each other with the second gate insulator GI2 interposed therebetween.

According to the embodiment of the disclosure, the second drain electrode DE2 and the second source electrode SE2 included in the third conductive layer CDL3 may be located between the interlayer dielectric layer ILD and the first passivation layer PSV1. For example, the second drain electrode DE2 and the second source electrode SE2 may be located on the interlayer dielectric layer ILD and covered by the first passivation layer PSV1. The second drain electrode DE2 and the second source electrode SE2 may be disposed in the same layer as the first drain electrode DE1 and the first source electrode SE1, which are disposed on the substrate SUB.

The second drain electrode DE2 may be electrically connected to the second drain region DR2 by at least one contact hole penetrating the interlayer dielectric layer ILD, and the second source electrode SE2 may be electrically connected to the second source region SR2 by at least one contact hole penetrating the interlayer dielectric layer ILD. The second source electrode SE2 according to the embodiment may be further electrically connected to the second bottom electrode BG2 in addition to the second source region SR2.

The first passivation layer PSV1 according to the embodiment may be located on the third conductive layer CDL3. The first passivation layer PSV1 may cover (e.g., entirely cover) the third conductive layer CDL3.

The first passivation layer PSV1 may protect circuit elements and lines provided in the panel circuit layer PCL from moisture penetration, etc. The first passivation layer PSV1 may have a multilayer structure including at least one inorganic film (e.g., an inorganic insulating layer) and an organic film (e.g., an organic insulating layer).

The first passivation layer PSV1 may include a first inorganic film IOL1 and a first organic film ORL1 sequentially disposed on the interlayer dielectric layer ILD in the third direction D3. The first inorganic film IOL1 may be disposed on the third conductive layer CDL3 and the interlayer dielectric layer ILD, and may be in contact with and cover the third conductive layer CDL3. The first inorganic film IOL1 may include silicon nitride. The first organic film ORL1 may be disposed on the first inorganic film IOL1 and may provide a flat surface over the first inorganic film IOL1 having level differences. The first organic film ORL1 may include an organic material.

The fourth conductive layer CDL4 according to the embodiment may be located between the first passivation layer PSV1 and the second passivation layer PSV2. For example, the fourth conductive layer CDL4 may be disposed on the first passivation layer PSV1 and covered by the second passivation layer PSV2.

The fourth conductive layer CDL4 may include a connection electrode CNE. The connection electrode CNE may be disposed on the first organic film ORL1 and covered by the second inorganic film IOL2. The connection electrode CNE may electrically connect the light-emitting element ED to the second transistor T2.

The second passivation layer PSV2 according to the embodiment may be located on the fourth conductive layer CDL4. The second passivation layer PSV2 may protect circuit elements and lines provided in the panel circuit layer PCL from moisture penetration, etc.

The second passivation layer PSV2 may have a multilayer structure including at least one inorganic film (e.g., an inorganic insulating layer) and an organic film (e.g., an organic insulating layer). The second passivation layer PSV2 may include a second inorganic film IOL2 and a second organic film ORL2 sequentially disposed on the first passivation layer PSV1 in the third direction D3. The second inorganic film IOL2 and the first inorganic film IOL1 may include the same material, and the second organic film ORL2 and the first organic film ORL1 may include the same material as the first organic film ORL1. The redundant descriptions will be omitted.

The electrodes, the conductive patterns and/or the lines provided in each of the first conductive layer CDL1, the second conductive layer CDL2, the third conductive layer CDL3 and the fourth conductive layer CDL4 of the panel circuit layer PCL may include at least one of: copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) and other metals, an alloy thereof, or other conductive material. Each of the electrodes, the conductive patterns and/or the lines may have a single-layer or multi-layer structure. The electrodes, the conductive patterns and/or the lines disposed in the same conductive layer may be formed simultaneously using the same conductive material.

According to the embodiment, the light-emitting element layer LEL may be disposed on the panel circuit layer PCL in the display area DA. The light-emitting element layer LEL may include light-emitting elements ED, a pixel-defining layer PDL and a spacer SPC.

According to the embodiment of the disclosure, the light-emitting element ED may include a first electrode ET1, an emissive layer EML, and a second electrode ET2 electrically connected to at least one pixel transistor Tpx.

According to the embodiment of the disclosure, the first electrode ET1 may be disposed on the panel circuit layer PCL. The first electrode ET1 may be disposed on the second passivation layer PSV2 and may be electrically connected to the connection electrode CNE through at least one contact hole or via hole penetrating the second passivation layer PSV2.

The first electrode ET1 may include a conductive metal material having a high reflectance. For example, the first electrode ET1 may have a single-layer structure of molybdenum (Mo), titanium (Ti), copper (Cu) or aluminum (Al), or may have a multi-layer structure including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au) or nickel (Ni), etc. (For example, ITO/Mg, ITO/MgF, ITO/Ag, ITO/Ag/ITO, etc.).

According to the embodiment of the disclosure, the emissive layer EML may include a high molecular material or a low molecular material. Light emitted from the emissive layer EML may contribute to displaying images. The emissive layer EML may be disposed in each of the pixels PX (see FIG. 3), and the emissive layer EML of each of the pixels PX may emit visible light of a color associated with the respective pixel PX.

According to the embodiment of the disclosure, the second electrode ET2 may include a conductive material. The second electrode ET2 may be a common electrode formed on the entire display area DA to cover the emissive layer EML and the pixel-defining layer PDL.

The second electrode ET2 may be formed of a transparent conductive material (TCO) such as ITO, IZO, ZnO and ITZO that can transmit light, or a semi-transmissive conductive material such as magnesium (Mg), silver (Ag) and an alloy of magnesium (Mg) and silver (Ag).

According to the embodiment of the disclosure, the pixel-defining layer PDL may define an opening OP and may expose a part of the pixel electrode AE through the opening OP. For example, the pixel-defining layer PDL may be formed to cover an edge of the first electrode ET1 of the light-emitting element ED, and may define an opening OP that exposes the remaining portion of the first electrode ET1. The area where the exposed first electrode ET1 and the emissive layer EML overlap each other (or an area including the same) may be defined as the emission area of each pixel PX.

The pixel-defining layer PDL may include at least one organic insulating layer containing an organic insulating material. For example, the pixel-defining layer PDL may include an acryl resin, an epoxy resin, a phenolic resin, a polyamide resin, a polyimide resin, an unsaturated polyester resin, a poly phenylen ether resin, a poly phenylene sulfide resin, benzocyclobutene (BCB), or other organic insulating materials.

According to the embodiment of the disclosure, the spacer SPC may be disposed on a part of the pixel-defining layer PDL. The spacer SPC may include at least one organic insulating layer containing an organic insulating material. The spacer SPC may include the same material as the pixel-defining layer PDL or may include a different material from the pixel-defining layer PDL. The pixel-defining layer PDL and the spacer SPC may be formed sequentially via respective mask processes. According to another embodiment, the pixel-defining layer PDL and the spacer SPC may be formed simultaneously using a halftone mask. For example, the pixel-defining layer PDL and the spacer SPC may be regarded as a single insulating film.

According to the embodiment of the disclosure, the encapsulation layer ENL may be disposed on the light-emitting element layer LEL. The encapsulation layer ENL may cover the light-emitting element layer LEL in the display area DA and may be extended to the non-display area NDA to be in contact with the panel circuit layer PCL. The encapsulation layer ENL can block the permeation of oxygen or moisture into the light-emitting element layer LEL and can alleviate electrical and/or physical shock on the panel circuit layer PCL and the light-emitting clement layer LEL.

The encapsulation layer ENL may have a multi-layer structure including a first encapsulation layer ENL1, a second encapsulation layer ENL2, and a third encapsulation layer ENL3 sequentially disposed in the third direction D3. Each of the first encapsulation layer ENL1 and the third encapsulating layer ENL3 may be an inorganic encapsulating layer containing an inorganic material, and the second encapsulation layer ENL2 may be an organic encapsulation layer containing an organic material. The structure and/or material of the encapsulation layer ENL may be altered depending on embodiments.

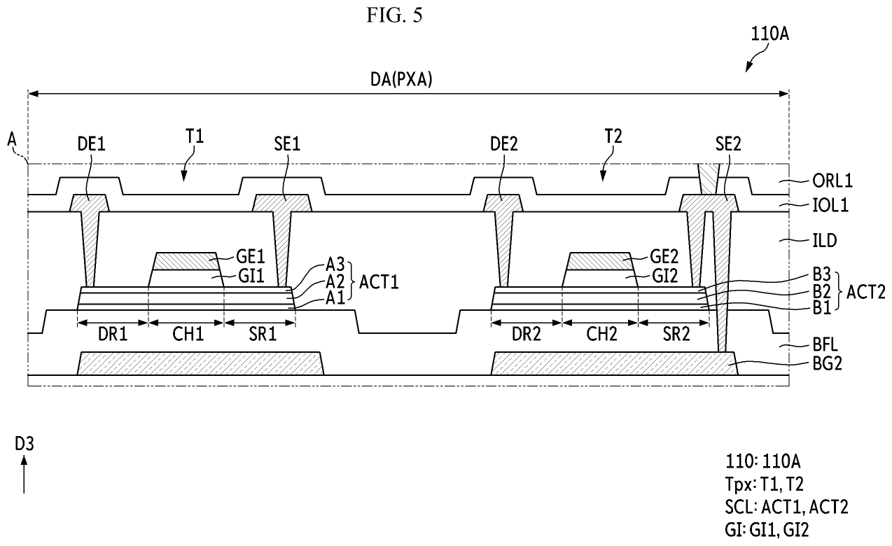

FIG. 5 is an enlarged schematic view of area A in FIG. 4.

Referring to FIG. 5 in conjunction with FIGS. 1 to 4, the first semiconductor layer ACT1 included in the semiconductor layer SCL according to the embodiment may include a first layer A1, a second layer A2, and a third layer A3 stacked on one another in the third direction D3. The first layer A1, the second layer A2, and the third layer A3 may be located such that the first layer A1, the second layer A2, and the third layer A3 overlap the first source region SR1, the first drain region DR1 and the first channel region CH1. The first layer A1 may be in contact with the buffer layer BFL, the third layer A3 may be in contact with the first gate insulator GI1, and the second layer A2 may be located between the first layer A1 and the third layer A3.

According to the embodiment of the disclosure, the first layer A1 may include at least one of gallium (Ga), zinc (Zn), and tin (Sn). For example, the first layer A1 may be an oxide semiconductor containing indium (In) content of about 30 at % to about 75 at % and containing at least one of gallium (Ga), zinc (Zn), and tin (Sn). For example, the first layer A1 may contain indium-gallium-zinc oxide (IGZO) or indium-tin-gallium oxide (ITGO).

According to the embodiment, the second layer A2 may contain all of gallium (Ga), zinc (Zn), and tin (Sn). For example, the second layer A2 may be an oxide semiconductor containing indium (In) content of about 30 at % to about 75 at % and containing all of gallium (Ga), zinc (Zn), and tin (Sn). For example, the second layer A2 may include indium-tin-gallium-zinc oxide (ITGZO).

According to the embodiment of the disclosure, the third layer A3 may include the same material as the first layer A1. The third layer A3 may include at least one of gallium (Ga), zinc (Zn), and tin (Sn). For example, the third layer A3 may be an oxide semiconductor containing indium (In) content of about 30 at % to about 75 at % and containing at least one of gallium (Ga), zinc (Zn), and tin (Sn). For example, the third layer A3 may contain indium-gallium-zinc oxide (IGZO) or indium-tin-gallium oxide (ITGO).

According to the embodiment of the disclosure, the content of indium (In) in the second layer A2 may be greater than the contents of indium (In) in the first layer A1 and the third layer A3. For example, the contents of indium (In) in the first layer A1 and the third layer A3 may have a range of about 30 at % to about 40 at %, and the content of indium (In) in the second layer A2 may have a range of about 65 at % to about 70 at %.

According to the embodiment of the disclosure, the first gate insulator GI1 may be disposed on the third layer A3 of the first semiconductor layer ACT1.

In the display panel 110 according to the embodiment, it is possible to optimize and/or stabilize the electrical characteristics of the first transistor TI by controlling the amount of nitrogen monoxide (NO), hydrogen (H₂) and/or oxygen (O₂) released from the first gate insulator GI1 during the fabrication process. For example, according to analysis on the first gate insulator GI1 by thermal desorption spectroscopy (TDS) using heat treatment (or thermal desorption gas spectroscopy using heat treatment) (e.g., heat treatment performed with a surface temperature in the range of about 50° C. to about 550° C.), the amount of nitrogen monoxide (NO) released may be about 2.5E+18 Molec./cm³ or less, the amount of hydrogen (H₂) released may be about 3E+19 Molec./cm³ or less, and the amount of oxygen (O₂) released may be about 2.76E+19 Molec./cm³ or less.

For example, in the display panel 110 according to the embodiment, the device characteristics of each transistor can be controlled by controlling the concentrations of nitrogen monoxide (NO), hydrogen (H₂) and oxygen (O₂) released from the first gate insulator GI1 even without forming a separate oxygen supply layer, etc., inside and/or around the transistors during the fabrication process. Accordingly, it is possible to simplify and/or reduce the fabrication process of the display panel 110, and accordingly increase the fabrication efficiency. Such a fabrication process will be described later.

The second semiconductor layer ACT2 included in the semiconductor layer SCL according to the embodiment may include a first layer B1, a second layer B2 and a third layer B3 stacked on one another in the third direction D3. The first layer B1, the second layer B2 and the third layer B3 may be located such that the first layer B1, the second layer B2, and the third layer B3 overlap the second source region SR2, the second drain region DR2, and the second channel region CH2.

The first layer B1, the second layer B2, and the third layer B3 included in the second semiconductor layer ACT2 may have the same structures and characteristics as the first layer A1, the second layer A2 and the third layer A3 included in the first semiconductor layer ACT1, respectively. The first layer B1 may be in contact with the buffer layer BFL, the third layer B3 may be in contact with the second gate insulator GI2, and the second layer B2 may be located between the first layer B1 and the third layer B3.

According to the embodiment of the disclosure, the first layer B1 may include indium-gallium-zinc oxide (IGZO) or indium-tin-gallium oxide (ITGO) containing indium (In) content of about 30 at % to about 75 at %, the second layer B2 may include indium-tin-gallium-zinc oxide (ITGZO) containing indium (In) content of about 30 at % to about 75 at %, and the third layer B3 may include the same material as the first layer B1. That is to say, the third layer B3 may include indium-gallium-zinc oxide (IGZO) or indium-tin-gallium oxide (ITGO) containing indium (In) content of about 30 at % to about 75 at %.

According to the embodiment of the disclosure, the content of indium (In) in the second layer B2 may be greater than the contents of indium (In) in the first layer B1 and the third layer B3. For example, the contents of indium (In) in the first layer B1 and the third layer B3 may have a range of about 30 at % to about 40 at %, and the content of indium (In) in the second layer B2 may have a range of about 65 at % to about 70 at %.

According to the embodiment of the disclosure, the second gate insulator GI2 may be disposed on the third layer B3 of the second semiconductor layer ACT2. The second gate insulator GI2 may have the same structure and material as the first gate insulator GI1. In the second gate insulator GI2, the amount of nitrogen monoxide (NO) released may be about 2.5E+18 Molec./cm³ or less, the amount of hydrogen (H₂) released may be about 3E+19 Molec./cm³ or less, and the amount of oxygen (O₂) released may be about 2.76E+19 Molec./cm³ or less.

In the display panel 110A according to the embodiment, it is possible to stabilize the electrical characteristics of the second transistor T2 by controlling the concentrations of nitrogen monoxide (NO), hydrogen (H₂) and/or oxygen (O₂) released from the second gate insulator GI2 during the fabrication process. Other redundant descriptions will be omitted.

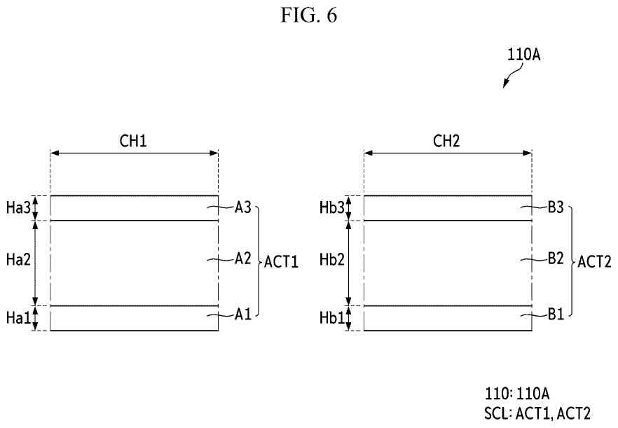

FIG. 6 is an enlarged schematic cross-sectional view of the semiconductor layer in FIG. 5. FIG. 6 shows an enlarged cross-sectional view of the first semiconductor layer ACT1 and the second semiconductor layer ACT2 included in the semiconductor layer SCL of FIG. 5.

Referring to FIG. 6 in conjunction with FIGS. 1 to 5, the height Ha2 of the second layer A2 included in the first semiconductor layer ACT1 may be greater than the height Ha1 of the first layer A1 and the height Ha3 of the third layer A3. The above-described heights and thicknesses may have the same meaning.

In some embodiments, the height Ha1 of the first layer A1 and the height Ha3 of the third layer A3 may range from about 20 angstroms to about 70 angstroms, and the height Ha2 of the second layer A2 may range from about 100 angstroms to about 200 angstroms.

The height Hb2 of the second layer B2 included in the second semiconductor layer ACT2 may be greater than the height Hb1 of the first layer B1 and the height Hb3 of the third layer B3.

In some embodiments, the height Hb1 of the first layer B1 and the height Hb3 of the third layer B3 may range from about 20 angstroms to about 70 angstroms, and the height Hb2 of the second layer B2 may range from about 100 angstroms to about 200 angstroms.

In the display panel 110A according to the embodiment, the first semiconductor layer ACT1 includes the first layer A1, the second layer A2, and the third layer A3 having different ranges of indium (In) contents, and the second semiconductor layer ACT2 includes the first layer B1, the second layer B2, and the third layer B3 having different ranges of indium (In) contents so that an oxide semiconductor having high mobility (e.g., an electron mobility in the range of about 60 cm²/Vs or higher) and an appropriate threshold voltage (e.g., a threshold voltage of about −2.0 V or higher) can be provided.

In the display panel 110A according to the embodiment, as the semiconductor layer SCL is formed with a high-mobility oxide semiconductor, the pixel transistors Tpx can be formed in a microscopic size (e.g., a size including a semiconductor layer having a width and/or length ranging from about several micrometers to about several tens of micrometers), while obtaining the mobility characteristics of the pixel transistors Tpx. Accordingly, the display panel 110A allows the pixel transistors Tpx to be readily arranged and/or formed even in a high-resolution display device with a relatively narrow pixel area, while obtaining the device characteristics and/or operating characteristics of the pixel transistors Tpx.

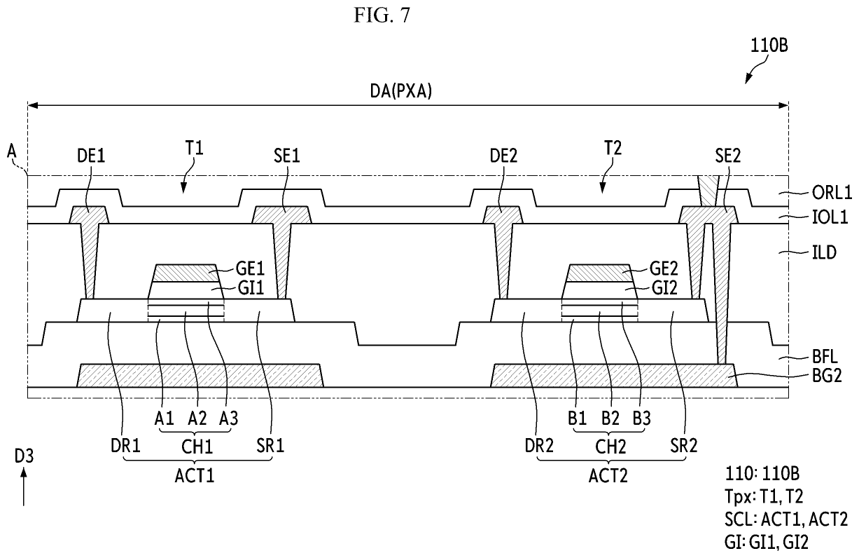

FIG. 7 is an enlarged schematic cross-sectional view of area A of FIG. 4 according to yet another embodiment.

Referring to FIG. 7 in conjunction with FIGS. 1 to 6, a semiconductor layer SCL of display panel 110B according to an embodiment of the disclosure may have a different shape from the semiconductor layer SCL of the display panel 110A. The the following description will focus on the difference and the redundant description will be omitted.

The first semiconductor layer ACT1 included in the semiconductor layer SCL of the display panel 110B may include a first layer A1, a second layer A2 and a third layer A3 stacked on one another in the third direction D3 in line with a first channel region CH1. For example, the first semiconductor layer ACT1 included in the semiconductor layer SCL of the display panel 110B may not include the first layer A1, the second layer A2 or the third layer A3 in a first drain region DR1 or a first source region SR1.

The first layer A1, the second layer A2, and the third layer A3 included in the first semiconductor layer ACT1 of the display panel 110B may have the same structure and material characteristics as the first layer A1, the second layer A2, and the third layer A3 included in the first semiconductor layer ACT1 of the display panel 110A. The redundant descriptions will be omitted.

The first semiconductor layer ACT1 overlapping the first drain region DR1 and the first source region SR1 of the display panel 110B may include the same material as the first layer A1 and/or the third layer A3 overlapping the first channel region CH1. For example, the first semiconductor layer ACT1 overlapping the first drain region DR1 and the first source region SR1 of the display panel 110B may be an oxide semiconductor containing indium (In) content of about 30 at % to about 75 at % and containing at least one of gallium (Ga), zinc (Zn), and tin (Sn). For example, the first semiconductor layer ACT1 overlapping the first drain region DR1 and the first source region SR1 may include either indium-gallium-zinc oxide (IGZO) or indium-tin-gallium oxide (ITGO).

The first semiconductor layer ACT1 overlapping the first drain region DR1 and the first source region SR1 of the display panel 110B may be formed via the same process as the first layer A1 overlapping the first channel region CH1, or may be formed via the same process as the third layer A3 overlapping the first channel region CH1.

The second semiconductor layer ACT2 included in the semiconductor layer SCL of the display panel 110B may include a first layer B1, a second layer B2, and a third layer B3 stacked on one another in the third direction D3 in line with the second channel region CH2. However, the second semiconductor layer ACT2 of the semiconductor layer SCL included in the display panel 110B may not include the first layer B1, the second layer B2, or the third layer B3 in a second drain region DR2 or a second source region SR2.

The first layer B1, the second layer B2, and the third layer B3 included in the second semiconductor layer ACT2 of the display panel 110B may have the same structure and material characteristics as the first layer A1, the second layer A2, and the third layer A3 included in the first semiconductor layer ACT1 of the display panel 110B. The redundant descriptions will be omitted.

The second semiconductor layer ACT2 overlapping the second drain region DR2 and the second source region SR2 of the display panel 110B may include the same material as the first layer B1 and/or the third layer B3 overlapping the second channel region CH2. For example, the second semiconductor layer ACT2 overlapping the second drain region DR2 and the second source region SR2 of the display panel 110B may be an oxide semiconductor containing indium (In) content of about 30 at % to about 75 at % and containing at least one of gallium (Ga), zinc (Zn), and tin (Sn). For example, the second semiconductor layer ACT2 overlapping the second drain region DR2 and the second source region SR2 may include either indium-gallium-zinc oxide (IGZO) or indium-tin-gallium oxide (ITGO).

The second semiconductor layer ACT2 overlapping the second drain region DR2 and the second source region SR2 of the display panel 110B may be formed via the same process as the first layer B1 overlapping the second channel region CH2, or may be formed via the same process as the third layer B3 overlapping the second channel region CH2.

The gate insulator GI included in the display panel 110B may have the same structural and material characteristics as the gate insulator GI included in the display panel 110A. The redundant descriptions will be omitted.

In the display panel 110B according to the embodiment, the first semiconductor layer ACT1 includes the first layer A1, the second layer A2 and the third layer A3 having different ranges of indium (In) contents which overlapping the first channel region CH1, and the second semiconductor layer ACT2 includes the first layer B1, the second layer B2, and the third layer B3 having different ranges of indium (In) contents which overlapping the second channel region CH2 so that an oxide semiconductor having high mobility (e.g., an electron mobility in the range of about 60 cm²/Vs or higher) and an appropriate threshold voltage (e.g., a threshold voltage of about −2.0 V or higher) can be provided.

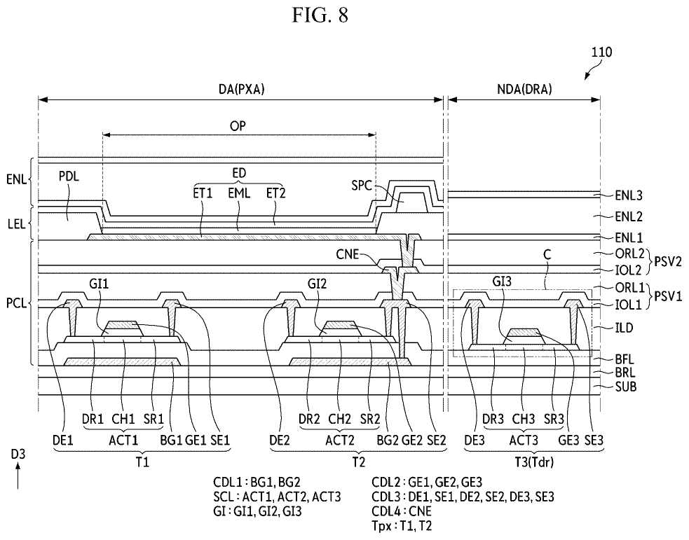

FIG. 8 is a schematic cross-sectional view showing the display panel across the display area and the non-display area NDA in FIG. 2.

Referring to FIG. 8 in conjunction with FIGS. 1 to 7, the structure of the display panel 110 in the display area DA may be identical as described above. Hereinafter, the structure of the display panel 110 in the display area DA will not be described, and the structure of the display panel 110 in the non-display area NDA will be described.

According to an embodiment of the disclosure, the display panel 110 may include a driving circuit area DRA in the non-display area NDA. The display panel 110 according to the embodiment may include a driver transistor Tdr provided or disposed in the driving circuit area DRA.

According to the embodiment, driver transistors Tdr may be provided in stage areas located in the driver circuit area DRA (e.g., stage areas where stage circuits of shift registers forming the first driver 120 are provided). In the following description, one driver transistor Tdr is shown in FIG. 8 as an example of the driver transistors Tdr, which will be referred to as a third transistor T3.

According to the embodiment, the third transistor T3 may include a semiconductor layer SCL, a second conductive layer CDL2, a third conductive layer CDL3, and a fourth conductive layer CDL4. For example, the third transistor T3 may include a third semiconductor layer ACT3 of the semiconductor layer SCL, a third gate electrode GE3 of the second conductive layer CDL2, and a third drain electrode DE3 and a third source electrode SE3 of the third conductive layer CDL3. Although the third transistor T3 includes the first conductive layer CDL1 in the drawings, the disclosure is not limited thereto. In some embodiments, the third transistor T3 may include the first conductive layer CDL1.

According to the embodiment, the third semiconductor layer ACT3 may be disposed between the buffer layer BFL and the interlayer dielectric layer ILD. For example, the third semiconductor layer ACT3 may be disposed on the buffer layer BFL and may be covered by the third gate insulator GI3 and the interlayer dielectric layer ILD. The third semiconductor layer ACT3 located in the non-display area NDA may be disposed in the same layer as the first semiconductor layer ACT1 and the second semiconductor layer ACT2 located in the display area DA.

The third semiconductor layer ACT3 may include a third channel region CH3 overlapping the third gate electrode GE3 in the third direction D3, and a third source region SR3 and a third drain region DR3 spaced apart from each other in a direction parallel to the substrate SUB with the third channel region CH3 therebetween. For example, the third source region SR3 and the third drain region DR3 may be located on the both ends of the third channel region CH3, respectively. The third channel region CH3 may not be conductive and can maintain semiconductor properties, and the third source region SR3 and the third drain region DR3 may be conductive regions.

The third semiconductor layer ACT3 may overlap the third gate electrode GE3 in the third direction D3. The third semiconductor layer ACT3 may include the same oxide semiconductor as the first semiconductor layer ACT1 and/or the second semiconductor layer ACT2 and may be formed together with the first semiconductor layer ACT1 and/or the second semiconductor layer ACT2. The first semiconductor layer ACT1, the second semiconductor layer ACT2 and the third semiconductor layer ACT3 may have the same structure and characteristics. More detailed descriptions will be given below.

According to the embodiment, the third gate electrode GE3 included in the second conductive layer CDL2 may be disposed between the third gate insulator GI3 and the interlayer dielectric layer ILD. For example, the third gate electrode GE3 may be located on the third gate insulator GI3 and may be covered by the interlayer dielectric layer ILD. The third gate electrode GE3 located in the non-display area NDA may be disposed in the same layer as the first gate electrode GE1 and the second gate electrode GE2 located in the display area DA.

The third gate electrode GE3 may be disposed on the third semiconductor layer ACT3 such that the third gate electrode GE3 overlaps the third channel region CH3. The third gate electrode GE3 and the third semiconductor layer ACT3 may be spaced apart from each other with the third gate insulator GI3 interposed therebetween.

According to the embodiment, the third drain electrode DE3 and the third source electrode SE3 included in the third conductive layer CDL3 may be located between the interlayer dielectric layer ILD and the first passivation layer PSV1. For example, the third drain electrode DE3 and the third source electrode SE3 may be located on the interlayer dielectric layer ILD and covered by the first passivation layer PSV1. The third drain electrode DE3 and the third source electrode SE3 located in the non-display area NDA may be disposed in the same layer as the first drain electrode DE1, the first source electrode SE1, the second drain electrode DE2, and the second source electrode SE2 located in the display area DA.

The third drain electrode DE3 may be electrically connected to the third drain region DR3 by at least one contact hole penetrating the interlayer dielectric layer ILD, and the third source electrode SE3 may be electrically connected to the third source region SR3 by at least one contact hole penetrating the interlayer dielectric layer ILD. According to another embodiment, the third transistor T3 may not include separate drain electrode and/or source electrode, and the third drain region DR3 and/or the third source region SR3 of the third semiconductor layer ACT3 may be electrically connected to other circuit elements, lines and/or conductive patterns to work as the drain electrode and/or source electrode of the third transistor T3.

The third gate insulator GI3 according to the embodiment may include the same material as the first gate insulator GI1 and/or the second gate insulator GI2, and may be formed together with the first gate insulator GI1 and/or the second gate insulator GI2. For example, the first gate insulator GI1, the second gate insulator GI2 and the third gate insulator GI3 may include the same insulating material (e.g., silicon oxide) and may be formed to have substantially equal or similar film quality. More detailed descriptions will be given below.

The third transistor T3 according to the embodiment may be covered by the first passivation layer PSV1, the second passivation layer PSV2, and the encapsulation layer ENL, and thus the circuit elements and lines provided in the panel circuit layer PCL can be protected from moisture penetration, etc. Other redundant descriptions will be omitted.

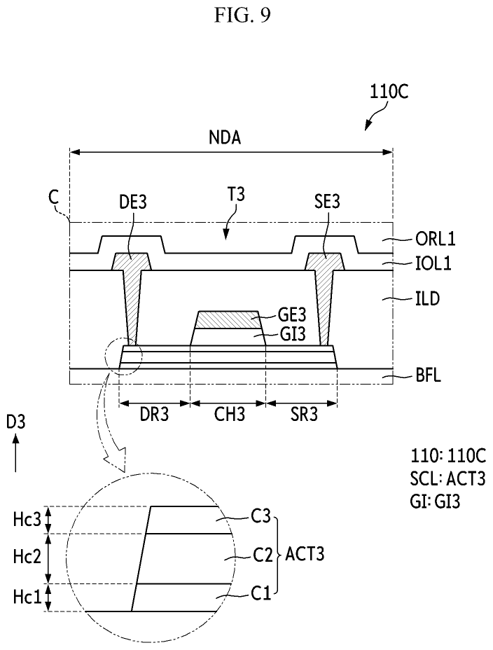

FIG. 9 is an enlarged schematic cross-sectional view of area C of FIG. 8.

Referring to FIG. 9, the third semiconductor layer ACT3 in the non-display area NDA may include a first layer C1, a second layer C2, and a third layer C3 stacked on one another in the third direction D3. The first layer C1, the second layer C2, and the third layer C3 may be located such that the first layer C1, the second layer C2, and the third layer C3 overlap the third source region SR3, the third drain region DR3, and the third channel region CH3.

The first layer C1, the second layer C2, and the third layer C3 included in the third semiconductor layer ACT3 may have the same structures and characteristics as the first layer A1, the second layer A2, and the third layer A3 included in the first semiconductor layer ACT1, respectively. The first layer C1 may be in contact with the buffer layer BFL, the third layer C3 may be in contact with the third gate insulator GI3, and the second layer C2 may be located between the first layer C1 and the third layer C3 in the third direction D3.

According to the embodiment, the first layer C1 may include indium-gallium-zinc oxide (IGZO) or indium-tin-gallium oxide (ITGO) containing indium (In) content of about 30 at % to about 75 at %, the second layer C2 may include indium-tin-gallium-zinc oxide (ITGZO) containing indium (In) content of about 30 at % to about 75 at %, and the third layer C3 may include the same material as the first layer C1. That is to say, the third layer C3 may include indium-gallium-zinc oxide (IGZO) or indium-tin-gallium oxide (ITGO) containing indium (In) content of about 30 at % to about 75 at %.

According to the embodiment of the disclosure, the content of indium (In) in the second layer C2 may be greater than the contents of indium (In) in the first layer C1 and the third layer C3. For example, the contents of indium (In) in the first layer C1 and the third layer C3 may have a range of about 30 at % to about 40 at %, and the content of indium (In) in the second layer C2 may have a range of about 65 at % to about 70 at %.

According to the embodiment of the disclosure, the third gate insulator GI3 may be disposed on the third layer C3 of the third semiconductor layer ACT3. The third gate insulator GI3 may have the same structure and material as the first gate insulator GI1 described above. In the third gate insulator GI3, the amount of nitrogen monoxide (NO) released may be about 2.5E+18 Molec./cm³ or less, the amount of hydrogen (H2) released may be about 3E+19 Molec./cm³ or less, and the amount of oxygen (O₂) released may be about 2.76E+19 Molec./cm³ or less.

In the display panel 110C according to the embodiment, it is possible to stabilize the electrical characteristics of the third transistor T3 by controlling the concentrations of nitrogen monoxide (NO), hydrogen (H2) and/or oxygen (O₂) released from the third gate insulator GI3. Other redundant descriptions will be omitted.

In some embodiments, the height Hc1 of the first layer C1 and the height Hc3 of the third layer C3 may range from about 20 angstroms to about 70 angstroms, and the height Hc2 of the second layer C2 may range from about 100 angstroms to about 200 angstroms.

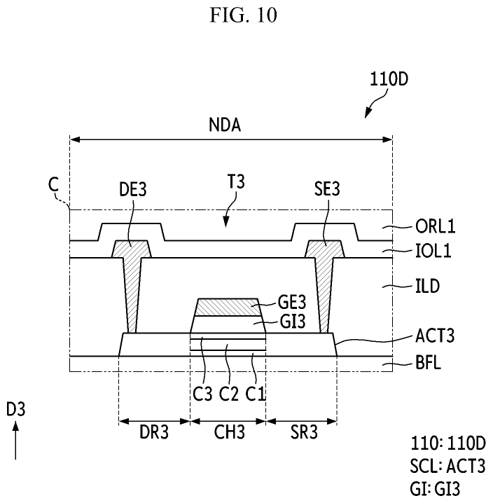

FIG. 10 is an enlarged schematic cross-sectional view of area C of FIG. 8 according to yet another embodiment.

Referring to FIG. 10, the third semiconductor layer ACT3 of the display panel 110B in the non-display area NDA may include a first layer C1, a second layer C2, and a third layer C3 stacked on one another in the third direction D3. It should be noted that the third semiconductor layer ACT3 included in the display panel 110B may not include the first layer C1, the second layer C2 or the third layer C3 in the third drain region DR3 or the third source region SR3.

The first layer C1, the second layer C2, and the third layer C3 included in the display panel 110B in line with the third channel region CH3 may have the same structure and material characteristics as the first layer C1, the second layer C2 and the third layer C3 included in the third semiconductor layer ACT3 of the display panel 110C of FIG. 9. The redundant descriptions will be omitted.

The third semiconductor layer ACT3 overlapping the third drain region DR3 and the third source region SR3 of the display panel 110B in the third direction D3 may include the same material as the first layer C1 and/or the third layer C3 overlapping the third channel region CH3. For example, the third semiconductor layer ACT3 overlapping the third drain region DR3 and the third source region SR3 of the display panel 110B may include indium-gallium-zinc oxide (IGZO) or indium-tin-gallium oxide (ITGO) that contains indium (In) content of about 30 at % to about 75 at % and contains at least one of gallium (Ga), zinc (Zn), and tin (Sn).

The third semiconductor layer ACT3 overlapping the third drain region DR3 and the third source region SR3 of the display panel 110B may be formed via the same process as the first layer C1 overlapping the third channel region CH3, or may be formed via the same process as the third layer C3 overlapping the third channel region CH3.

In the non-display area NDA, the third gate insulator GI3 included in the display panel 110D may have the same structural and material characteristics as the third gate insulator GI3 included in the display panel 110C of FIG. 9. The redundant descriptions will be omitted.

In the display panel 110D according to the embodiment, the third semiconductor layer ACT3 includes the first layer C1, the second layer C2, and the third layer C3 having different ranges of indium (In) contents which overlapping the first channel region CH1 so that an oxide semiconductor having high mobility (e.g., an electron mobility in the range of about 60 cm²/Vs or higher) and an appropriate threshold voltage (e.g., a threshold voltage of about −2.0 V or higher) can be provided.

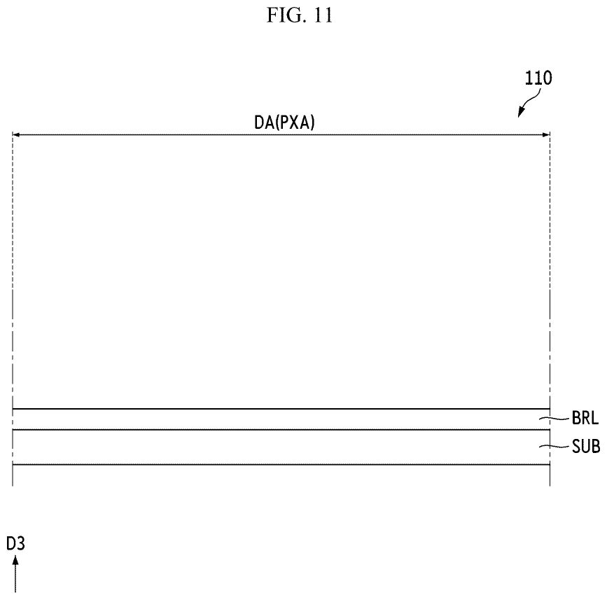

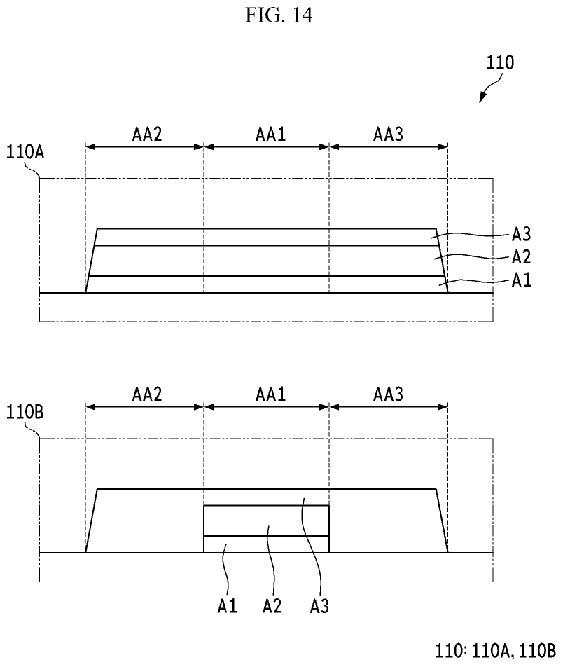

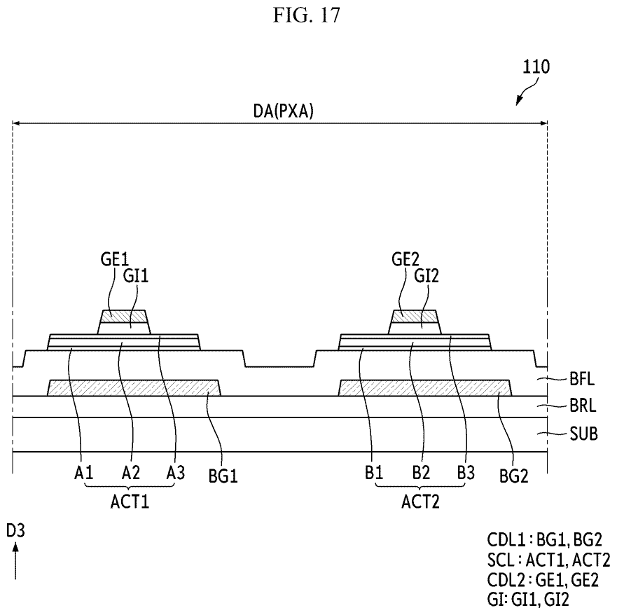

FIGS. 11 to 19 are cross-sectional schematic views showing processing steps for fabricating the pixel transistors shown in FIG. 5. FIGS. 11 to 19 sequentially show steps of forming pixel transistors Tpx on a substrate SUB among the steps of fabricating the display panel 110 of FIG. 5.

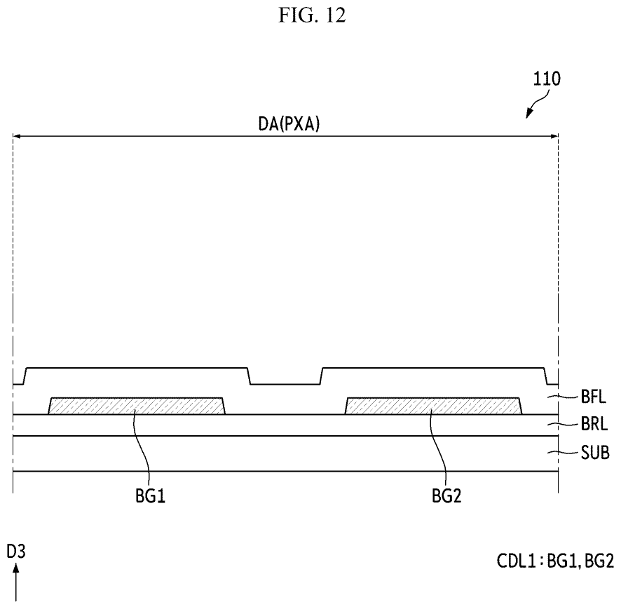

Referring to FIGS. 11 and 12, a substrate SUB including a display area DA may be formed, and then a barrier layer BRL may be formed on the substrate SUB. In this process, the display area DA of the substrate SUB may include a pixel area PXA, and the barrier layer BRL may be formed via a film formation process (e.g., a deposition process) of an insulating film using at least one of the above-listed insulating materials (e.g., an inorganic insulating material). The material and/or method for forming the barrier layer BRL may vary depending on embodiments.

Subsequently, a first conductive layer CDLI may be formed on the barrier layer BRL. The first conductive layer CDL1 may include a first bottom electrode BG1 and a second bottom electrode BG2. The first bottom electrode BG1 and the second bottom electrode BG2 may be formed in the pixel area PXA and may be spaced apart from each other.

The first bottom electrode BG1 and the second bottom electrode BG2 may be formed via a film formation process of a conductive film (e.g., a deposition process) and a patterning process of the conductive film (e.g., an etching process using a mask). The material and/or method for forming the first bottom electrode BG1 and the second bottom electrode BG2 may vary depending on embodiments.

Subsequently, a buffer layer BFL covering the first conductive layer CDL1 may be formed. The buffer layer BFL may be formed via a deposition process of forming a film of at least one of the above-listed insulating materials (e.g., an inorganic insulating material). The material and/or method for forming the buffer layer BFL may vary depending on embodiments.

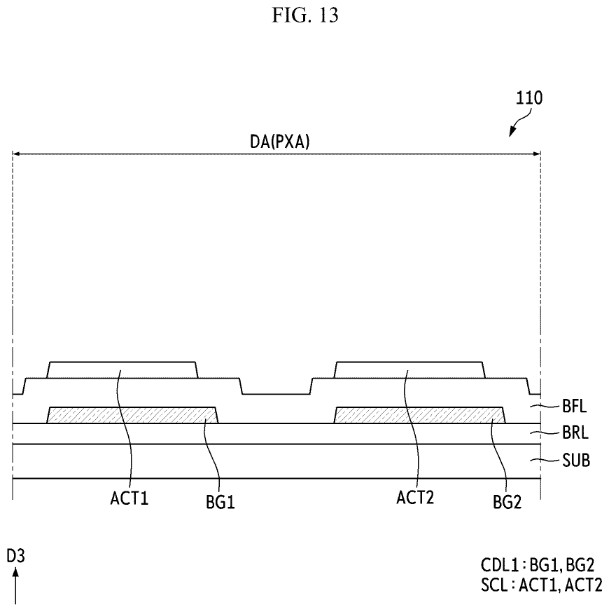

Subsequently, referring to FIGS. 13 to 15, a semiconductor layer SCL is formed on the buffer layer BFL. The semiconductor layer SCL may be formed via a sputtering deposition process. The semiconductor layer SCL may include a first semiconductor layer ACT1 and a second semiconductor layer ACT2.

The semiconductor layer SCL may be positioned in line with the first conductive layer CDL1 in the third direction D3. The first semiconductor layer ACT1 may overlap the first bottom electrode BG1 in the third direction D3, and the second semiconductor layer ACT2 may overlap the second bottom electrode BG2 in the third direction D3.

In this process, the first semiconductor layer ACT1 may include a first layer A1, a second layer A2, and a third layer A3 that are stacked on one another in this order. As described above, the first layer A1 and the third layer A3 may include indium-gallium-zinc oxide (IGZO) or indium-tin-gallium oxide (ITGO), and the second layer A2 may include indium-tin-gallium-zinc oxide (ITGZO).

Different indium (In) contents of the first layer A1, the second layer A2 and the third layer A3 can be obtained by controlling the indium (In) ratio of the sputtering target to about 30 at % to about 75 at % in the fabrication process, thereby forming the first layer A1, the second layer A2 and the third layer A3 having different indium (In) contents.

The second semiconductor layer ACT2 may include a first layer B1, a second layer B2 and a third layer B3 that are stacked on one another in this order. The first layer B1 of the second semiconductor layer ACT2 may be formed together with the first layer A1 of the first semiconductor layer ACT1, the second layer B2 of the second semiconductor layer ACT2 may be formed together with the second layer A2 of the first semiconductor layer ACT1, and the third layer B3 of the second semiconductor layer ACT2 may be formed together with the third layer A3 of the first semiconductor layer ACT1.

Accordingly, the first layer B1, the second layer B2 and the third layer B3 included in the second semiconductor layer ACT2 may include the same structural and material characteristics as the first layer A1, the second layer A2 and the third layer A3 included in the first semiconductor layer ACT1. The redundant descriptions will be omitted.

In this process, the semiconductor layer SCL of the display panel 110 may include various structures depending on the process conditions. For example, the display panel 110 may have the shape of the display panel 110A in which the first layer A1, the second layer A2 and the third layer A3 of the first semiconductor layer ACT1 are formed across the first area AA1, the second area AA2 and the third area AA3, or the shape of the display panel 110B in which the first layer A1, the second layer A2 and the third layer A3 are formed only in the first area AA1.

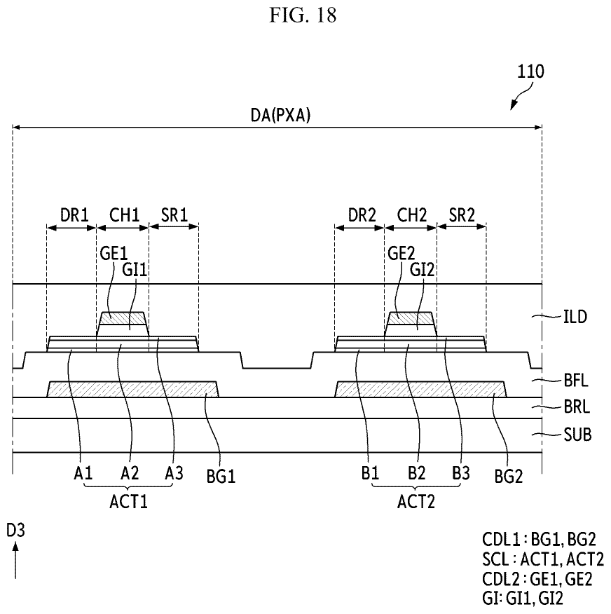

In this process, the first area AA1 may refer to the same part as the first channel region CH1 of FIG. 18, the second area AA2 may refer to the same part as the first drain region DR1 of FIG. 18, and the third area AA3 may refer to the same part as the first source region SR1 of FIG. 18. Although not shown in the drawings, the second semiconductor layer ACT2 may have the same structural characteristics as the first semiconductor layer ACT1.

Hereinafter, subsequent processes of the display panel 110 will be described using the structure of the display panel 110A as an example.

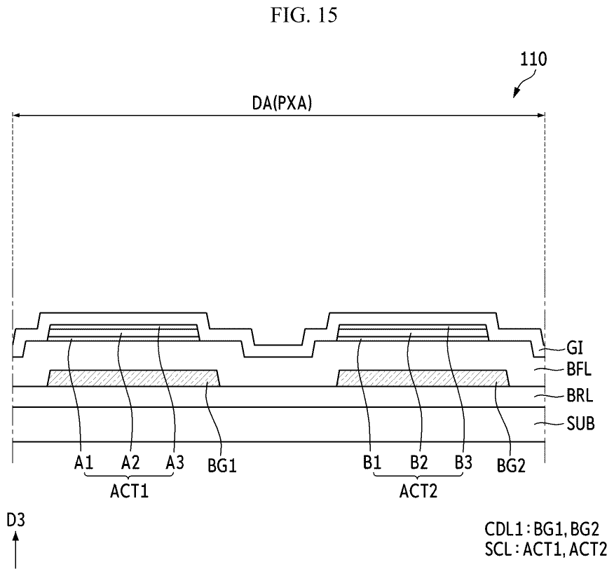

Referring to FIG. 15, a gate insulator GI may be formed on the semiconductor layer SCL. The gate insulator GI may be in contact with the first semiconductor layer ACT1 and the second semiconductor layer ACT2 and may cover (e.g., entirely cover) the first semiconductor layer ACT1 and the second semiconductor layer ACT2. The gate insulator GI may include silicon oxide.

This process may be carried out by controlling at least one of the deposition pressure, the deposition power, the distance between the deposition device and the target substrate, and the flow rate ratio of the deposition gas in order to control the film quality of the gate insulator GI.

Accordingly, in the gate insulator GI during this process, the amount of nitrogen monoxide (NO) released may be about 2.5E+18 Molec./cm³ or less, the amount of hydrogen (H2) released may be about 3E+19 Molec./cm³ or less, and the amount of oxygen (O₂) released may be about 2.76E+19 Molec./cm³ or less.

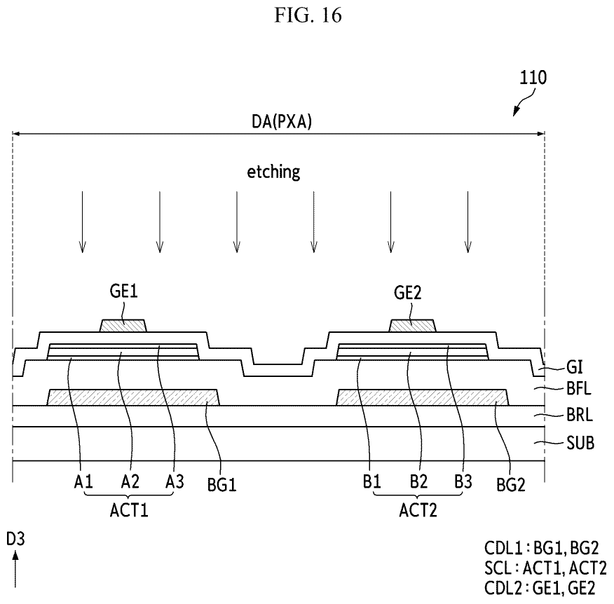

Subsequently, referring to FIGS. 16 to 18, a second conductive layer CDL2 including a first gate electrode GE1 and a second gate electrode GE2 may be formed on the gate insulator GI. In this process, the first gate electrode GE1 may overlap the first semiconductor layer ACT1 in the third direction D3, and the second gate electrode GE2 may overlap the second semiconductor layer ACT2 in the third direction D3.

In this process, the first gate electrode GE1 and the second gate electrode GE2 may be formed together using the same conductive material. For example, the first gate electrode GE1 and the second gate electrode GE2 may be formed together via a process of forming a conductive film using at least one of the above-listed conductive materials and a process of patterning the conductive film. The material and/or method for forming the first gate electrode GE1 and the second gate electrode GE2 may vary depending on embodiments.

Subsequently, the gate insulator GI may be etched to have a shape conforming to each of the first gate electrode GE1 and the second gate electrode GE2. This process may be carried out using a separate mask, or the first gate electrode GE1 and the second gate electrode GE2 may be used as masks to etch the gate insulator GI.

Via this process, a first gate insulator GI1 in line with the first gate electrode GE1 and a second gate insulator GI2 in line with the second gate electrode GE2 may be separately formed. For example, the first gate insulator GI1 may be formed on a part of the first semiconductor layer ACT1 in line with the first gate electrode GE1, and may have a shape and/or size corresponding to the shape and/or size of the first gate electrode GE1. The second gate insulator GI2 may be formed on a part of the second semiconductor layer ACT2 in line with the second gate electrode GE2, and may have a shape and/or size corresponding to the shape and/or size of the second gate electrode GE2.

In this process, each of the first semiconductor layer ACT1 and the second semiconductor layer ACT2 may be divided into multiple regions having different characteristics. For example, a part of the first semiconductor layer ACT1 that overlaps the first gate electrode GE1 in the third direction D3 may be as the first channel region CH1, one side of the first semiconductor layer ACT1 that does not overlap the first gate electrode GE1 in the third direction D3 may become the first source region SR1, and the opposite side of the first semiconductor layer ACT1 that does not overlap the first gate electrode GE1 in the third direction D3 may become the first drain region DR1.

For example, in this process, oxygen vacancy may occur in the first drain region DR1 and the first source region SR1 of the first semiconductor layer ACT1. Accordingly, the first semiconductor layer ACT1 may be divided into the first drain region DR1, the first source region SR1 and the first channel region CH1 having different characteristics. In some embodiments, the oxygen vacancy may even spread to a portion of the first channel region CH1 that overlaps the first gate electrode GE1.

Similarly, a portion of the second semiconductor layer ACT2 that overlaps the second gate electrode GE2 may be defined as a second channel region CH2, and both ends of the second channel region CH2 may be divided into a second source region SR2 and a second drain region DR2.

In this process, oxygen vacancy may occur in the second drain region DR2 and the second source region SR2 of the second semiconductor layer ACT2, and accordingly, the second semiconductor layer ACT2 may be divided into the second drain region DR2, the second source region SR2 and the second channel region CH2 having different properties.

Subsequently, an interlayer dielectric layer ILD covering the semiconductor layer SCL, the second conductive layer CDL2, and the gate insulator GI may be formed. The interlayer dielectric layer ILD may be formed via a process of forming an insulating film using at least one of the above-listed insulating materials (e.g., an inorganic insulating material). The material and/or method for forming the interlayer dielectric layer ILD may vary depending on embodiments.

In this process, hydrogen may be introduced into the first semiconductor layer ACT1 and the second semiconductor layer ACT2. Therefore, through this process, the portions of the first semiconductor layer ACT1 and the second semiconductor layer ACT2 where oxygen vacancy occurred may become conductive (e.g., into the n type). The first drain region DR1 and the first source region SR1 of the first semiconductor layer ACT1 and the second drain region DR2 and the second source region SR2 of the second semiconductor layer ACT2 may become conductive.

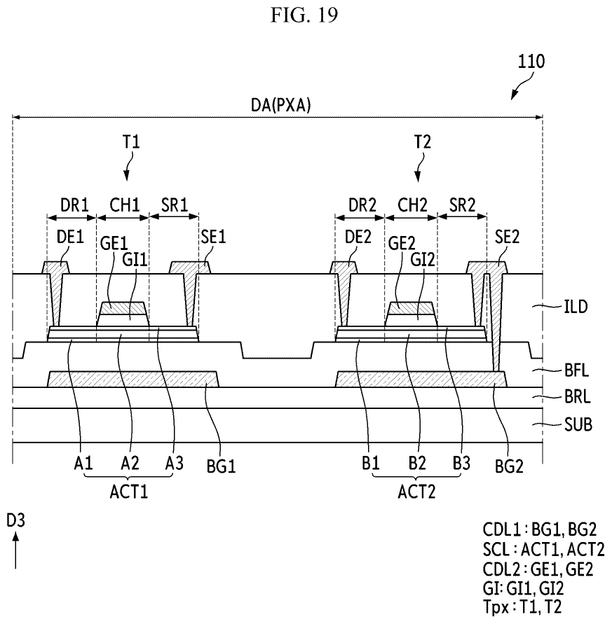

Subsequently, referring to FIG. 19, prior to the formation of a first drain electrode DE1, a first source electrode SE1, a second drain electrode DE2 and a second source electrode SE2, multiple contact holes may be formed in the interlayer dielectric layer ILD.

Subsequently, the first drain electrode DE1, the first source electrode SE1, the second drain electrode DE2 and the second source electrode SE2 may be formed on the interlayer dielectric layer ILD.

The first drain electrode DE1 and the first source electrode SE1 may be formed to be electrically connected to different parts of the first semiconductor layer ACT1. For example, the first drain electrode DE1 may be electrically connected to the first drain region DR1, and the first source electrode SE1 may be electrically connected to the first source region SR1. The second drain electrode DE2 and the second source electrode SE2 may be formed to be electrically connected to different parts of the second semiconductor layer ACT2. For example, the second drain electrode DE2 may be electrically connected to the second drain region DR2, and the second source electrode SE2 may be electrically connected to the second source region SR2. the second source electrode SE2 may be further electrically connected to the second bottom electrode BG2. The redundant descriptions will be omitted.

For example, pixel transistors Tpx including the first transistor T1 and the second transistor T2 may be formed in the display area DA.

The display device according to one embodiment of the present disclosure can be applied to various electronic devices. The electronic device according to the one embodiment of the present disclosure includes the display device described above, and may further include modules or devices having additional functions in addition to the display device.

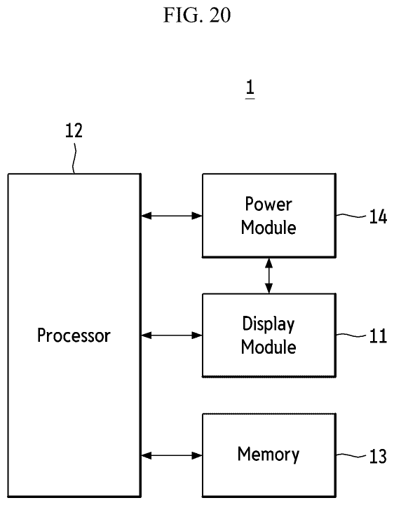

FIG. 20 is a schematic block diagram of an electronic device according to one embodiment of the present disclosure.

Referring to FIG. 20, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. Some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

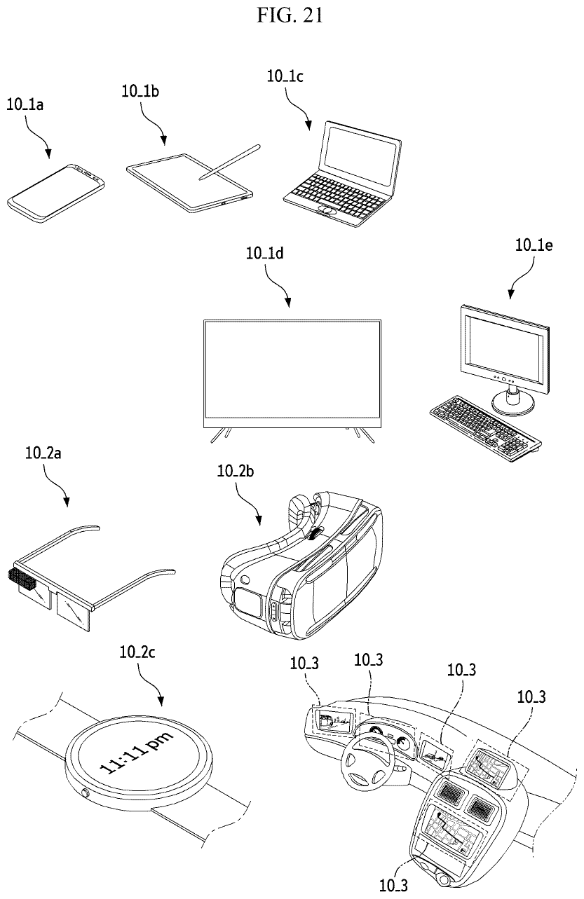

FIG. 21 is a schematic diagram of an electronic device according to various embodiments of the present disclosure.

Referring to FIG. 21, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a substrate including a display area and a non-display area;
a first transistor including a first semiconductor layer disposed on the display area of the substrate and a first gate electrode disposed on the first semiconductor layer; and
a first gate insulator disposed between the first semiconductor layer and the first gate electrode,
wherein the first semiconductor layer includes a first layer and a second layer stacked on one another each other in a direction perpendicular to the substrate, and
an indium content of the second layer is higher than an indium content of the first layer, and a height of the first layer is lower than a height of the second layer.

2. The display device of claim 1, wherein the first layer includes an oxide semiconductor containing indium content of about 30 at % to about 40 at %, and the second layer includes an oxide semiconductor containing indium content of about 65 at % to about 70 at %.

3. The display device of claim 2, wherein the first layer includes either indium-gallium-zinc oxide (IGZO) or indium-tin-gallium oxide (ITGO), and the second layer includes indium-tin-gallium-zinc oxide (ITGZO).

4. The display device of claim 3, wherein the height of the first layer ranges from about 20 angstroms to about 70 angstroms, and the height of the second layer ranges from about 100 angstroms to about 200 angstroms.

5. The display device of claim 1, wherein the first layer is in contact with the first gate insulator,
wherein the first gate insulator includes silicon oxide.

6. The display device of claim 5, wherein in the first gate insulator, an amount of nitrogen monoxide released is about 2.5E+18 Molec./cm³ or less, an amount of hydrogen released is about 3E+19 Molec./cm³, and an amount of oxygen released is about 2.76E+19 Molec./cm³ or less under heat treatment conditions carried out at a temperature ranging from about 50° C. to about 550° C.

7. The display device of claim 1, wherein the first semiconductor layer includes a channel region overlapping the first gate insulator, and a source region and a drain region located on ends of the channel region,
the first gate insulator overlaps the channel region, and
the first gate insulator is an insulating pattern that exposes the drain region and the source region.

8. The display device of claim 7, wherein the first layer and the second layer are located to overlap the channel region, the source region, and the drain region.

9. The display device of claim 7, wherein the first layer and the second layer overlap the channel region, and the first layer and the second layer do not overlap the source region or the drain region.

10. The display device of claim 1, wherein the first semiconductor layer further includes a third layer spaced apart from the first layer in a direction perpendicular to the substrate with the second layer interposed therebetween,
the first layer and the third layer include a same material,
a height of the third layer is lower than a height of the second layer, and
the height of the third layer ranges from about 20 angstroms to about 70 angstroms.

11. The display device of claim 1, further comprising:
a second transistor disposed on the non-display area of the substrate and including a second semiconductor layer and a second gate electrode disposed on the second semiconductor layer; and
a second gate insulator disposed between the second semiconductor layer and the second gate electrode.

12. The display device of claim 11, wherein the second semiconductor layer and the first semiconductor layer are disposed in a same layer in the non-display area,
the second semiconductor layer includes a first sub-layer having same material and height as the first layer; and a second sub-layer having same material and height as the second layer, and
the second semiconductor layer is disposed in the non-display area, and further includes a third sub-layer spaced apart from the first sub-layer with the second sub-layer interposed therebetween in a direction perpendicular to the substrate.

13. A method for fabricating a display device, the method comprising:
forming a semiconductor layer on a substrate;
forming a gate insulator on the semiconductor layer; and
forming a gate electrode on the gate insulator,
wherein the semiconductor layer includes a first layer, a second layer and a third layer that are stacked on one another in this order, and
an indium content of the first layer and an indium content of the third layer are lower than an indium content of the second layer.

14. The method of claim 13, wherein the first layer, the second layer and the third layer overlap the gate electrode and the gate insulator in a direction perpendicular to the substrate.

15. The method of claim 14, wherein heights of the first layer and the third layer are lower than a height of the second layer.

16. An electronic device comprising:
a display device including a display element layer disposed on a substrate,
wherein the display element layer includes:
a substrate including a display area and a non-display area;
a first transistor including a first semiconductor layer disposed on the display area of the substrate and a first gate electrode disposed on the first semiconductor layer; and
a first gate insulator disposed between the first semiconductor layer and the first gate electrode,
the first semiconductor layer includes a first layer and a second layer stacked on one another each other in a direction perpendicular to the substrate, and
an indium content of the second layer is higher than an indium content of the first layer, and a height of the first layer is lower than a height of the second layer.

17. The electronic device of claim 16, wherein the first layer includes an oxide semiconductor containing indium content of about 30 at % to about 40 at %, and the second layer includes an oxide semiconductor containing indium content of about 65 at % to about 70 at %.

18. The electronic device of claim 17, wherein the first layer includes either indium-gallium-zinc oxide (IGZO) or indium-tin-gallium oxide (ITGO), and the second layer includes indium-tin-gallium-zinc oxide (ITGZO).

19. The electronic device of claim 18, wherein the height of the first layer ranges from about 20 angstroms to about 70 angstroms, and the height of the second layer ranges from about 100 angstroms to about 200 angstroms. wherein the first gate insulator includes silicon oxide.

20. The electronic device of claim 16, wherein the electronic device is at least one of a smart phone, a tablet PC (personal computer), a computer, a television (TV), a desk monitor, wearable electronic devices including smart glasses, a head mounted display, and a smart watch, and vehicle electronic devices including Center Information Display (CID) and a room mirror display arranged on a dashboard, center fascia, and dashboard of an automobile.
